(19) United States
(12) Patent Application Publication
(10) Pub. No.: US 2026/0323893 A1
(43) Pub. Date: Oct. 15, 2026

(54) DISPLAY DEVICE AND ELECTRONIC DEVICE INCLUDING THE DISPLAY DEVICE

(71) Applicant: Samsung Display Co., LTD., Yongin-si (KR)

(72) Inventor: Hyeon Ji KIM, Yongin-si (KR)

(21) Appl. No.: 19/535,023

(22) Filed: Feb. 10, 2026

(30) Foreign Application Priority Data
Apr. 11, 2025 (KR) 10-2025-0047315

(51) Int. Cl. H05K 7/20; H05K 5/00

(52) U.S. Cl. CPC H05K 7/20963; H05K 5/0018

(57) ABSTRACT

A display device includes a display panel, a panel support member overlapping with the display panel, a connecting member connected to the display panel, a circuit board connected to the connecting member and comprising a touch integrated circuit, and a heat dissipation member which dissipates heat generated in the touch integrated circuit.

This application claims priority to Korean Patent Application No. 10-2025-0047315, filed on Apr. 11, 2025, and all the benefits accruing therefrom under 35 U.S.C. § 119, the content of which in its entirety is herein incorporated by reference.

### BACKGROUND

### 1. Field

The present disclosure relates to a display device and an electronic device including the display device.

### 2. Description of the Related Art

Typically, electronic devices such as a smart phone, a tablet PC, a digital camera, a laptop computer, a navigation device and a smart TV include a display device for displaying images.

A display device may include a plurality of light-emitting elements. The plurality of light-emitting elements can display images through power applied from an external source. Some of the power applied to the light-emitting elements may not be converted into light energy but may be accumulated in the display device in the form of heat energy. The heat accumulated in the display device is one of the main causes of deterioration of the display quality of the display device.

As display devices become capable of higher-performance and smaller, the electronic components inside display devices also become more highly integrated, and accordingly the heat density increases. Under the circumstances, a technology that can more effectively remove the generated heat is desired.

### SUMMARY

Aspects of the present disclosure provide a display device that can effectively dissipate heat generated in an electronic component in the display device, and an electronic device including the display device.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a display device includes a display panel, a panel support member overlapping with the display panel, a connecting member connected to the display panel, a circuit board connected to the connecting member and including a touch integrated circuit, and a heat dissipation member which dissipates heat generated in the touch integrated circuit.

The touch integrated circuit protrudes from the circuit board, and the heat dissipation member covers at least a part of the touch integrated circuit.

The heat dissipation member entirely covers a protruding surface and side surfaces of the touch integrated circuit.

The heat dissipation member includes a first heat dissipation member covering the protruding surface of the touch integrated circuit, and a second heat dissipation member covering the side surfaces of the touch integrated circuit and side surfaces of the first heat dissipation member.

The side surfaces of the touch integrated circuit covered by the second heat dissipation member protrude from the circuit board.

The circuit board overlaps with the panel support member when the connecting member is bent, and the heat dissipation member is placed inside the panel support member.

The heat dissipation member overlaps with the touch integrated circuit.

The display device further includes an adhesive sheet arranged between the panel support member and the circuit board, wherein the heat dissipation member is in contact with the adhesive sheet.

The display device further includes an adhesive sheet overlapping with the panel support member, wherein the circuit board comes into contact with the adhesive sheet when the connecting member is bent, and the heat dissipation member is placed inside the adhesive sheet.

The heat dissipation member overlaps with the touch integrated circuit.

The heat dissipation member is in contact with the panel support member and the circuit board.

According to an aspect of the present disclosure, a display device includes a display panel, a panel support member overlapping with the display panel, a connecting member connected to the display panel, and a circuit board connected to the connecting member and including a touch integrated circuit, wherein a heat release area formed in the circuit board is overlapping with the touch integrated circuit.

The display device further includes an adhesive sheet overlapping with the panel support member, wherein the circuit board comes into contact with the adhesive sheet when the connecting member is bent.

The heat release area is depressed into the circuit board from a surface of the circuit board, and the surface of the circuit board comes in contact with the adhesive sheet when the connecting member is bent.

A part of the adhesive sheet is removed such that a removal area is formed, and the removal area overlaps with the heat release area.

The display device further includes a heat dissipation member placed inside the heat release area.

The heat dissipation member overlaps with the touch integrated circuit.

According to an aspect of the present disclosure, an electronic device includes a display panel, a panel support member overlapping with the display panel, a connecting member connected to the display panel, a circuit board connected to the connecting member and including a touch integrated circuit, and a heat dissipation member which dissipates heat generated in the touch integrated circuit.

The touch integrated circuit protrudes from the circuit board, and the heat dissipation member covers at least a part of the touch integrated circuit.

The electronic device further includes at least one of a processor, a memory in which data on one or more of the display panel and the processor is stored, and a power module which supplies power to the display panel, the processor and the memory.

According to an embodiment of the present disclosure, by arranging a heat dissipation member inside a display device, it is possible to effectively dissipating heat generated in an electronic component in the display device.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan view illustrating a display device according to a first embodiment of the present disclosure when a connecting member is unfolded.

FIG. 2 is a rear view of the display device illustrated in FIG. 1.

FIG. 3 is a view illustrating the display device illustrated in FIG. 2 when the connecting member is bent.

FIG. 4 is a side view illustrating a part of the display device illustrated in FIG. 1.

FIG. 5 is a cross-sectional view illustrating the display panel of FIG. 4.

FIG. 6 is an enlarged view of portion A of FIG. 1.

FIG. 7 is a cross-sectional view taken along line B-B′ of FIG. 6.

FIG. 8 is a plan view illustrating a display device according to a second embodiment of the present disclosure when a connecting member is unfolded.

FIG. 9 is a view illustrating the display device illustrated in FIG. 8 when the connecting member is bent.

FIG. 10 is an enlarged view of portion C of FIG. 9.

FIG. 11 is a cross-sectional view taken along line D-D′ of FIG. 10.

FIG. 12 is a view illustrating the heat dissipation member placed in the heat dissipation space in FIG. 11.

FIG. 13 is a view illustrating a heat dissipation member placed inside an adhesive sheet.

FIG. 14 is a view illustrating a heat dissipation member placed inside a panel support member.

FIG. 15 is a block diagram of an electronic device according to an embodiment of the present disclosure.

FIG. 16 is a view illustrating electronic devices according to a variety of embodiments of the present disclosure.

### DETAILED DESCRIPTION

Advantages and features of the present disclosure and methods to achieve them will become apparent from the descriptions of example embodiments hereinbelow with reference to the accompanying drawings. However, the present disclosure is not limited to example embodiments disclosed herein but may be implemented in various different ways. The example embodiments are provided for making the disclosure of the present disclosure thorough and for fully conveying the scope of the present disclosure to those skilled in the art. It is to be noted that the scope of the present disclosure is defined by the claims.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are illustrative and are not limiting.

Although terms such as first, second, and the like are used to distinguish arbitrarily between the elements such terms describe, and thus these terms are not necessarily intended to indicate temporal or other prioritization of such elements. These terms are used to distinguish one element from another. Accordingly, as used herein, a first element may be a second element within the technical scope of the present disclosure.

Features of various example embodiments of the present disclosure may be combined partially or totally. As will be clearly appreciated by those skilled in the art, technically various interactions and operations are possible. Various example embodiments can be practiced individually or in combination.

Hereinafter, example embodiments of the present disclosure will be described in detail with reference to the accompanying drawings.

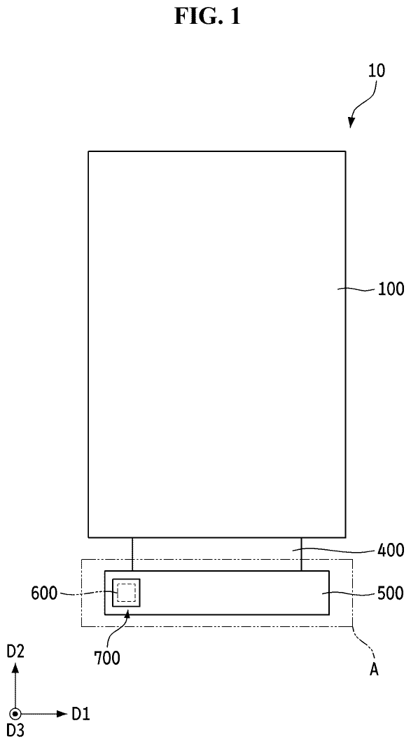

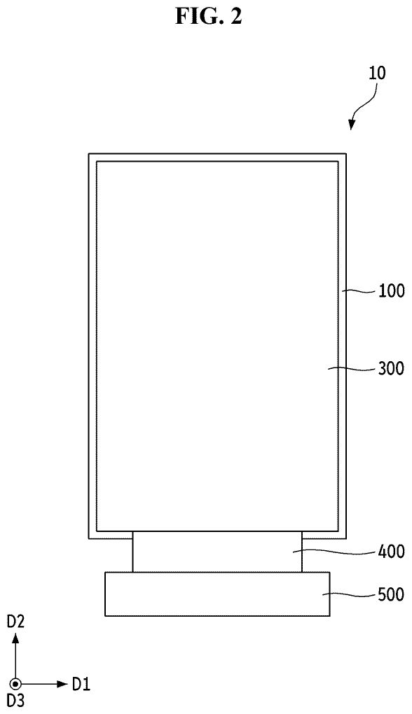

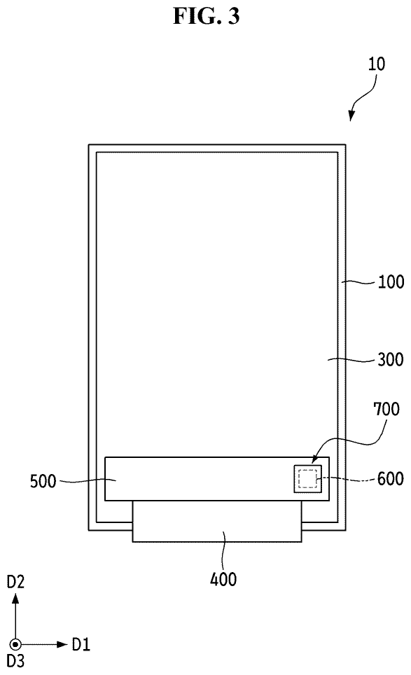

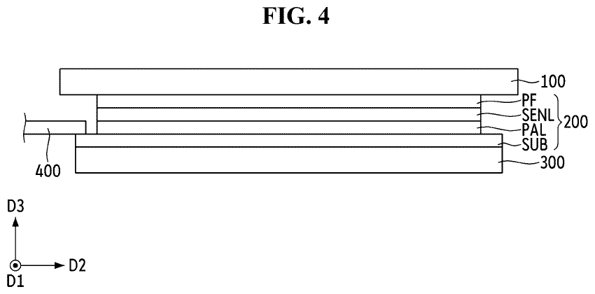

FIG. 1 is a plan view illustrating a display device according to a first embodiment of the present disclosure when a connecting member is unfolded. FIG. 2 is a rear view of the display device illustrated in FIG. 1. FIG. 3 is a view illustrating the display device illustrated in FIG. 2 when the connecting member is bent. FIG. 4 is a side view illustrating a part of the display device illustrated in FIG. 1.

As used herein, a display device 10 according to an example embodiment of the present disclosure is for displaying moving images or still images. The display device 10 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things. Alternatively, the display device 10 may be used as a display screen applied to the center fascia of a vehicle.

The display device 10 may be a light-emitting display device such as an organic light-emitting display device using organic light-emitting diodes, a quantum-dot light-emitting display device including quantum-dot light-emitting layer, an inorganic light-emitting display device including an inorganic semiconductor, and a micro light-emitting display device using micro light-emitting diodes (LED). In the following description, an organic light-emitting display device is described as an example of the display device 10. It is, however, to be understood that embodiments of the present disclosure are not limited thereto.

The first direction D1 may refer to a direction parallel to a side of the display device 1, for example, the horizontal direction of the display device 10 when viewed from the top. A second direction D2 may refer to a direction parallel to another side of the display device 10 that meet the side of the display device 10, for example, the vertical direction of the display device 10 when viewed from the top. A third direction D3 may refer to the thickness direction of the display device 10.

The display device 10 may have a quadrangular shape, such as a rectangular shape when viewed from the top. For example, the display device 10 may have a shape similar to a rectangle having shorter sides in the first direction D1 and longer sides in the second direction D2 when viewed from the top. The corners where the shorter sides in the first direction D1 meet the longer sides in the second direction D2 may be rounded with a predetermined curvature or may be a right angle. The shape of the display device 10 when viewed from the top is not limited to a rectangular shape but may be formed in another polygonal shape, a circular shape, or an elliptical shape.

The display device 10 may include a display area and a non-display area. The shape of the display area may follow the shape of the display device 10 when viewed from the top. In an example in which the display device 10 has a rectangular shape when viewed from the top, the display area may also have a rectangular shape when viewed from the top.

The display area may include a plurality of pixels to display images. The non-display area may not include pixels and thus may not display images. The non-display area may be located around the display area. The non-display area may surround the display area, but the embodiments of the present disclosure are not limited thereto. The display area may be partially surrounded by the non-display area.

Referring to FIGS. 1 to 4, the display device 10 according to the first embodiment of the present disclosure may include a cover window 100, a display panel 200, a panel support member 300, a connecting member 400, a circuit board 500, a touch integrated circuit 600, and a heat dissipation member 700.

The cover window 100 may include a material with high light transmittance. The cover window 100 may include a polymer resin such as polyimide or glass. The cover window 100 may be attached onto a polarizing film PF of the display panel 200 by an adhesive member such as an optically clear adhesive (OCA) film.

The display panel 200 may be disposed under the cover window 100. The display panel 200 may have a rectangular shape having shorter sides in the first direction D1 and longer sides in the second direction D2 when viewed from the top. In the display panel 200, the corners where the shorter sides in the first direction D1 meet the longer sides in the second direction D2 may be formed at a right angle or may be rounded with a predetermined curvature. The display panel 200 may have a quadrangular shape other than a rectangle, a polygonal shape other than a quadrangular shape, a circular shape, an oval shape, or an irregular shape when viewed from the top.

The display panel 200 may include a display area where a plurality of emission areas that emits light is arranged, and a non-display area disposed around the display area. The non-display area may surround the display area. A plurality of display pads may be disposed in the non-display area at one edge of the display panel 200.

The display panel 200 may include a substrate SUB, a display unit PAL, a sensor unit SENL and a polarizing film PF.

The substrate SUB may be formed of an insulating material such as glass, quartz and a polymer resin. The substrate SUB may be a rigid substrate or a flexible substrate that can be bent, folded, rolled, and so on.

The display unit PAL may be placed on the substrate SUB. The display unit PAL may be a layer including a plurality of emission areas that emit light. The display unit PAL may include a buffer film, a thin-film transistor layer on which thin-film transistors are disposed, a light-emitting element layer that emits light, and an encapsulating layer for encapsulating the light-emitting element layer.

The sensor unit SENL may be placed on the display unit PAL. The sensor unit SENL may include sensor electrodes and may sense whether there is a user's touch.

The polarizing film PF may be placed on the sensor unit SENL. The polarizing film PF can prevent the deterioration of image visibility of the display panel 200 due to reflection of external light. The polarizing film may include a linear polarizer and a retardation film such as a λ/4 (quarter-wave) plate. The phase retardation film may be placed on the sensor unit SENL, and the linear polarizer may be placed on the phase retardation film. The cover window 100 may be placed on the polarizing film PF.

The panel support member 300 may be located under the substrate SUB. The panel support member 300 may be attached to the lower surface of the substrate SUB by an adhesive member. The adhesive member may be a pressure-sensitive adhesive (PSA). The panel support member 300 may include at least one of: a light-absorbing member for absorbing light incident from outside, a buffer member for absorbing external impact, and a heat dissipating member for efficiently discharging heat from the display panel 200.

The light-absorbing member may be located under the substrate SUB. The light-absorbing member blocks the transmission of light to prevent the elements disposed thereunder from being seen from above the display panel 200, such as the circuit board 500. The light-absorbing member may include a light-absorbing material such as a black pigment and a black dye.

The buffer member may be located under the light-absorbing member. The buffer member absorbs an external impact to prevent the display panel 200 from being damaged. The buffer member may be made up of a single layer or multiple layers. For example, the buffer member may be formed of a polymer resin such as polyurethane, polycarbonate, polypropylene and polyethylene, or may be formed of a material having elasticity such as a rubber and a sponge obtained by foaming a urethane-based material or an acrylic-based material.

The heat dissipating member may be located under the buffer member. The heat dissipation member may include a first heat dissipation layer including graphite or carbon nanotubes, and a second heat dissipation layer formed of a thin metal film such as copper, nickel, ferrite and silver, which can block electromagnetic waves and have high thermal conductivity.

The connecting member 400 may be connected to a plurality of display pads of the display panel 200 through a conductive adhesive member such as an anisotropic conductive film. Accordingly, the display panel 200 and the connecting member 400 may be electrically connected with each other.

In some aspects, the connecting member 400 may be connected to a plurality of circuit pads of the circuit board 500 through a conductive adhesive member such as an anisotropic conductive film. As a result, the connecting member 400 and the circuit board 500 may be electrically connected with each other.

The connecting member 400 may be a flexible printed circuit board or a chip-on film.

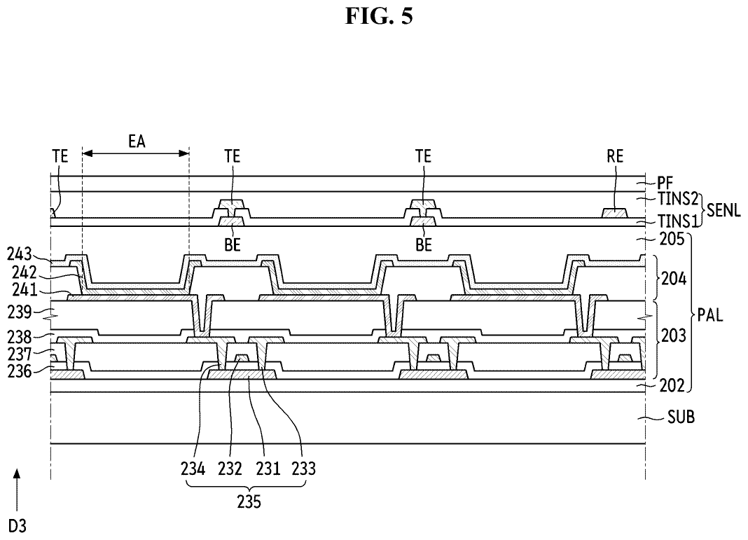

FIG. 5 is a cross-sectional view illustrating the display panel of FIG. 4.

Referring to FIG. 5, the display unit PAL may include a buffer layer 202 (also referred to herein as a buffer film), a thin-film transistor layer 203, a light-emitting element layer 204, and an encapsulation layer 205.

The buffer layer 202 may be formed on the substrate SUB. The buffer layer 202 may be formed on the substrate SUB to protect the thin-film transistors 235 and the light-emitting elements from moisture permeating through the substrate SUB that is susceptible to moisture permeation. The buffer layer 202 may be formed of a plurality of inorganic layers stacked on one another alternately. For example, the buffer layer 202 may be made up of multiple layers in which one or more inorganic layer of a silicon oxide layer (SiOx), a silicon nitride layer (SiNx) and SiON are stacked on one another alternately. The buffer layer 202 may be eliminated.

The thin-film transistor layer 203 is formed on the buffer layer 202. The thin-film transistor layer 203 includes thin-film transistors 235, a gate insulator 236, an interlayer dielectric layer 237, a protective layer 238, and an organic layer 239.

Each of the thin-film transistor 235 includes an active layer 231, a gate electrode 232, a source electrode 233, and a drain electrode 234. In FIG. 5, the thin-film transistors 235 are implemented as top-gate transistors in which the gate electrode 232 is located above the active layer 231. It is, however, to be understood that embodiments of the present disclosure are not limited thereto. That is to say, the thin-film transistors 235 may be implemented as bottom-gate transistors in which the gate electrode 232 is located below the active layer 231, or as double-gate transistors in which the gate electrodes 232 are located above and below the active layer 231.

The active layer 231 is formed on the buffer layer 202. The active layer 231 may be formed of a silicon-based semiconductor material or an oxide-based semiconductor material. For example, the active layer 231 may be formed of polycrystalline silicon, amorphous silicon, or an oxide semiconductor. A light-blocking layer for blocking external light incident on the active layer 231 may be formed between the buffer layer 202 and the active layer 231.

The gate insulator 236 may be formed on the active layer 231. The gate insulator 236 may be formed of an inorganic layer, for example, a silicon oxide layer (SiOx), a silicon nitride layer (SiNx), or a multilayer thereof.

The gate electrode 232 may be formed on the gate insulator 236. The gate electrode 232 and the gate lines may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The interlayer dielectric layer 237 may be formed over the gate electrodes 232 and the gate lines. The interlayer dielectric layer 237 may be formed as an inorganic layer, for example, a silicon oxide layer (SiOx), a silicon nitride layer (SiNx), or as multiple layers thereof.

The source electrode 233 and the drain electrode 234 may be formed on the interlayer dielectric layer 237. Each of the source electrode 233 and the drain electrode 234 may be connected to the active layer 231 through a contact hole penetrating through the gate insulator 236 and the interlayer dielectric layer 237. The source electrode 233 and the drain electrode 234 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The protective layer 238 may be formed on the source electrode 233 and the drain electrode 234 in order to insulate the thin-film transistors 235. The protective layer 238 may be formed of an inorganic layer, e.g., a silicon oxide layer (SiOx), a silicon nitride layer (SiNx), or a multilayer thereof.

The organic layer 239 may be formed on the protective layer 238 to provide a flat surface over the thin-film transistors 335 having difference levels. The organic layer 239 may be implemented as an organic film such as an acryl resin, an epoxy resin, a phenolic resin, a polyamide resin and a polyimide resin.

The light-emitting element layer 204 is formed on the thin-film transistor layer 203. The light-emitting element layer 204 includes the light-emitting elements and a bank.

The light-emitting elements and the bank are formed on the organic layer 239. An organic light-emitting device including an anode electrode 241, emissive layers 242 and a cathode electrode 243 is employed as an example of the light-emitting elements.

The anode electrode 241 may be formed on the organic layer 239. The anode electrode 241 may be connected to the source electrode 233 of the thin-film transistor 235 via a contact hole penetrating through the protective layer 238 and the organic layer 239.

The bank may be formed such that the bank covers the edge of the anode electrode 241 on the organic layer 239 and defines the emission areas EA of the pixels. That is to say, the bank may define the emission areas EA of the pixels. In each of the pixels, the anode electrode 241, the emissive layer 242 and the cathode electrode 243 are sequentially stacked on one another such that holes from the anode electrode 241 and electrons from the cathode electrode 243 combine in the emissive layer 242 to emit light.

The emissive layers 242 are formed on the anode electrode 241 and the bank. The emissive layers 242 may be organic emissive layers. The emissive layers 242 may emit one of red light, green light, and blue light. Alternatively, the emissive layer 242 may be a white emissive layer that emits white light. In such case, the red emissive layer, the green emissive layer and the blue emissive layer may be stacked on one another or may be formed commonly across the pixels as a common layer. In such case, the display panel 200 may further include additional color filters for representing red, green and blue colors.

The emissive layer 242 may include a hole transporting layer, a light-emitting layer, and an electron transporting layer. In some aspects, the emissive layer 242 may be formed in a tandem structure of two or more stacks, in which case a charge generating layer may be formed between the stacks.

The cathode electrode 243 is formed on the emissive layer 242. The cathode electrode 243 may be formed such that the cathode electrode 243 covers the emissive layer 242. The cathode electrode 243 may be a common layer formed across the pixels.

When the light-emitting element layer 204 is of a top-emission type in which light exits toward the upper side, the anode electrode 241 may be formed of a metal material having a high reflectivity such as a stack structure of aluminum and titanium (Ti/Al/Ti), a stack structure of aluminum and ITO (ITO/Al/ITO), an APC alloy and a stack structure of APC alloy and ITO (ITO/APC/ITO). The APC alloy is an alloy of silver (Ag), palladium (Pd) and copper (Cu). The cathode electrode 243 may be formed of a transparent conductive material (TCP) such as ITO and IZO that can transmit light, or a semi-transmissive conductive material such as magnesium (Mg), silver (Ag) and an alloy of magnesium (Mg) and silver (Ag). In an example in which the cathode electrode 243 is formed of a translucent conductive material, the light extraction efficiency can be increased by using microcavities.

When the light-emitting element layer 204 is of a bottom-emission type in which light exits toward the lower side, the anode electrode 241 may be formed of a transparent conductive material (TCP) such as ITO and IZO that can transmit light, or a semi-transmissive conductive material such as magnesium (Mg), silver (Ag) and an alloy of magnesium (Mg) and silver (Ag). The cathode electrode 243 may be formed of a metal material having a high reflectivity such as a stack structure of aluminum and titanium (Ti/Al/Ti), a stack structure of aluminum and ITO (ITO/Al/ITO), an APC alloy and a stack structure of APC alloy and ITO (ITO/APC/ITO). In an example in which the anode electrode 241 is formed of a translucent conductive material, the light extraction efficiency can be increased by using microcavities.

The encapsulation layer 205 is formed on the light-emitting element layer 204. The encapsulation layer 205 serves to prevent permeation of oxygen or moisture into the emissive layer 242 and the cathode electrode 243. To this end, the encapsulation layer 205 may include at least one inorganic film. The inorganic film may be formed of silicon nitride, aluminum nitride, zirconium nitride, titanium nitride, hafnium nitride, tantalum nitride, silicon oxide, aluminum oxide, or titanium oxide. In some aspects, the encapsulation layer 205 may further include at least one organic film. The organic film may have a sufficient thickness to prevent particles from permeating into the encapsulation layer 205 and entering the emissive layer 242 and the cathode electrode 243. The organic film may include one of epoxy, acrylate and urethane acrylate.

The sensor unit SENL may be formed on the encapsulation layer 205. In an example in which the sensor unit SENL is formed directly on the encapsulation layer 205, the thickness of the display device 10 can be reduced, compared with a display device in which a separate touch panel is attached on the encapsulation layer 205.

The sensor unit SENL may include sensor electrodes for sensing a user's touch by capacitive sensing, and touch lines for connecting the pads with the sensor electrodes. For example, the sensor unit SENL can sense a user's touch by self-capacitance sensing or mutual capacitance sensing. In the example illustrated in FIG. 5, the sensor unit SENL is made up of two layers including driving electrodes TE, sensing electrodes RE and bridge electrodes BE connecting between the driving electrodes TE for mutual capacitance sensing.

The bridge electrodes BE may be formed on the encapsulation layer 205. The bridge electrodes BE may be made up of, but is not limited to, a stack structure of aluminum and titanium (Ti/Al/Ti), a stack structure of aluminum and ITO (ITO/Al/ITO), an APC alloy and a stack structure of APC alloy and ITO (ITO/APC/ITO). For example, the bridge electrodes BE may be made up of a single layer of molybdenum (Mo), titanium (Ti), copper (Cu), aluminum (Al) or ITO.

A first sensing insulating layer TINS1 is formed over the bridge electrodes BE. The first sensing insulating layer TINS1 may be formed of an inorganic film, for example, a silicon nitride layer, a silicon oxynitride layer, a silicon oxide layer, a titanium oxide layer, or an aluminum oxide layer.

The driving electrodes TE and the sensing electrodes RE may be formed on the first sensing insulating layer TINS1. The driving electrode TE and the sensing electrode RE may be formed as, but is not limited to, a stack structure of aluminum and titanium (Ti/Al/Ti), a stack structure of aluminum and ITO (ITO/Al/ITO), an APC alloy and a stack structure of APC alloy and ITO (ITO/APC/ITO). For example, the driving electrodes TE and the sensing electrodes RE may be made up of a single layer of molybdenum (Mo), titanium (Ti), copper (Cu), aluminum (Al) or ITO.

Contact holes may be formed in the first sensing insulating layer TINS1 which penetrate the first sensing insulating layer TINS1 to expose the bridge electrodes BE. The driving electrodes TE may be connected to the bridge electrodes BE through the contact holes.

A second sensing insulating layer TINS2 is formed over the driving electrodes TE and the sensing electrodes RE. The second sensing insulating layer TINS2 may provide a flat surface over the driving electrodes TE, the sensing electrodes RE and the bridge electrodes BE which have different heights. The second sensing insulating layer TINS2 may be formed of an organic layer such as an acryl resin, an epoxy resin, a phenolic resin, a polyamide resin and a polyimide resin.

The bridge electrodes BE connecting between the adjacent driving electrodes TE may be located on the encapsulation layer 205, and the driving electrodes TE and the sensing electrodes RE may be located on the first sensing insulating layer TINS1. Therefore, the driving electrodes TE and the sensing electrodes RE may be electrically separated from each other at their intersections, while the sensing electrodes RE may be electrically connected with one another in a direction, and the driving electrodes TE may be electrically connected with one another in another direction.

The polarizing film PF may be placed on the second sensing insulating layer TINS2 and can prevent the deterioration of image visibility of the display panel 200 due to reflection of external light.

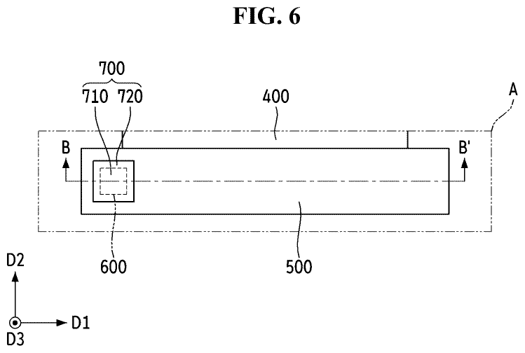

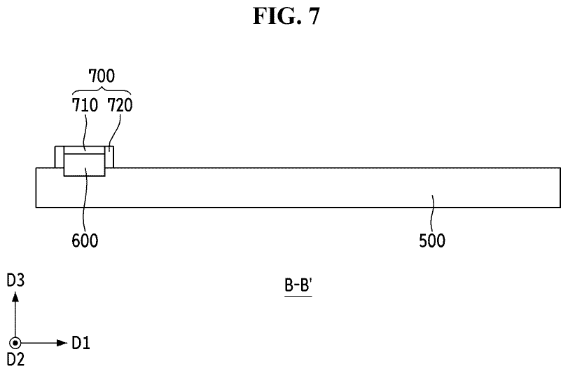

FIG. 6 is an enlarged view of portion A of FIG. 1. FIG. 7 is a cross-sectional view taken along line B-B′ of FIG. 6.

Referring to FIGS. 6 and 7, the circuit board 500 may be electrically connected to the display panel 200 by the connecting member 400. The circuit board 500 may be a flexible printed circuit board (FPCB) that can be bent, a rigid printed circuit board (PCB) that is not easily bent, or a composite printed circuit board including both a rigid printed circuit board and a flexible printed circuit board. The circuit board 500 may overlap with the panel support member 300 when the connecting member 400 is bent.

The circuit board 500 may process the signal converted by a control circuit board (not illustrated) and transmit the signal to the display panel 200.

The touch integrated circuit 600 may detect a user's touch and generate a touch driving signal. The touch integrated circuit 600 may protrude from the circuit board 500 in the third direction D3. The shape of the touch integrated circuit 600 may be a rectangle when viewed from the top, but embodiments of the present disclosure are not limited thereto. For example, the touch integrated circuit 600 may have a rectangular protruding surface when the touch integrated circuit 600 is viewed in the third direction D3.

The heat dissipation member 700 may cover at least a part of the touch integrated circuit 600 and may dissipate heat generated in the touch integrated circuit 600. The heat dissipation member 700 may entirely cover the protruding surface and the side surfaces of the touch integrated circuit 600. The heat dissipation member 700 may include a first heat dissipation member 710 and a second heat dissipation member 720.

The first heat dissipation member 710 may cover the protruding surface of the touch integrated circuit 600. The shape of the first heat dissipation member 710 may conform to the shape of the touch integrated circuit 600 when viewed from the top. The first heat dissipation member 710 may cover the entire protruding surface of the touch integrated circuit 600. The first heat dissipation member 710 may be provided as a heat dissipation sheet having a thickness.

The second heat dissipation member 720 may cover side surfaces of the touch integrated circuit 600 and side surfaces of the first heat dissipation member 710. The second heat dissipation member 720 may be provided as a heat dissipation sheet having a thickness. The side surfaces of the touch integrated circuit 600 covered by the second heat dissipation member 720 on the circuit board 500 may protrude from the circuit board 500. The second heat dissipation member 720 may cover the side surfaces of the first heat dissipation member 710.

The second heat dissipation member 720 may be provided as a heat dissipation resin instead of a heat dissipation sheet. In an example in which the second heat dissipation member 720 is provided as a heat dissipation resin, the second heat dissipation member 720 may be applied to the side surfaces of the first heat dissipation member 710 and the side surfaces of the touch integrated circuit 600 and cover the side surfaces of the first heat dissipation member 710 and the side surfaces of the touch integrated circuit 600.

While the first heat dissipation member 710 and the second heat dissipation member 720 may be provided as separate sheets, both the first heat dissipation member 710 and the second heat dissipation member 720 may be provided as heat dissipation resins. In an example in which the first heat dissipation member 710 and the second heat dissipation member 720 are provided as heat dissipation resins, the heat dissipation resins may be applied to the touch integrated circuit 600 and cover all areas of the touch integrated circuit 600 protruding from the circuit board 500.

As described herein, since the heat dissipation member 700 covers the touch integrated circuit 600, the heat dissipation member 700 can dissipate the heat generated in the touch integrated circuit 600.

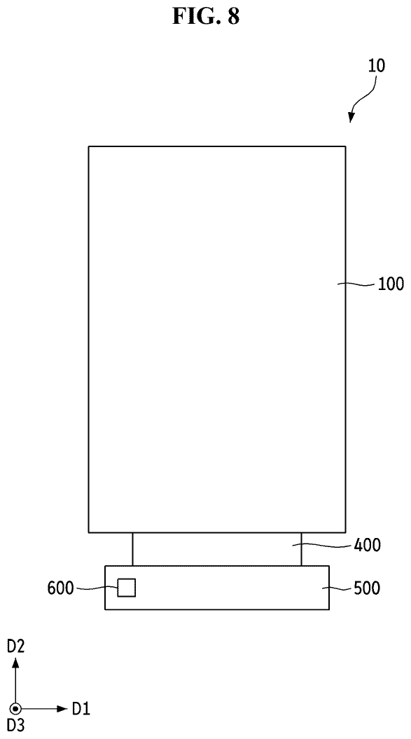

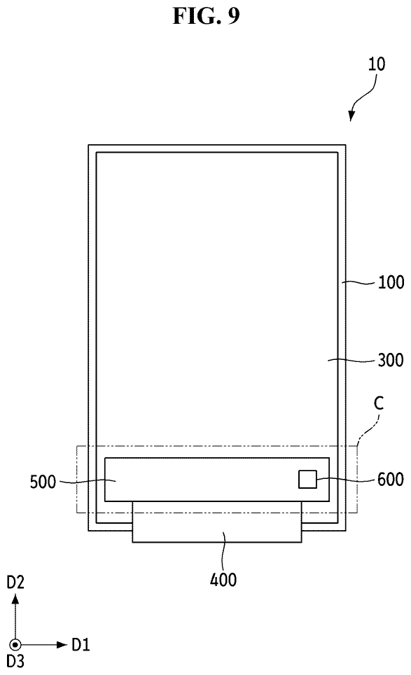

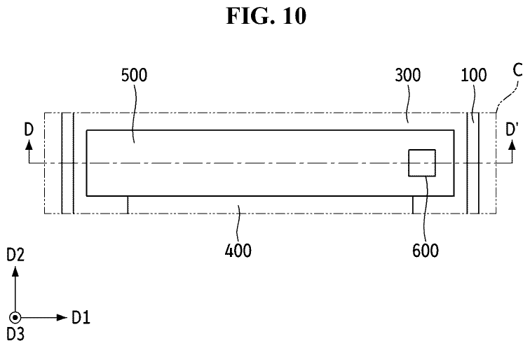

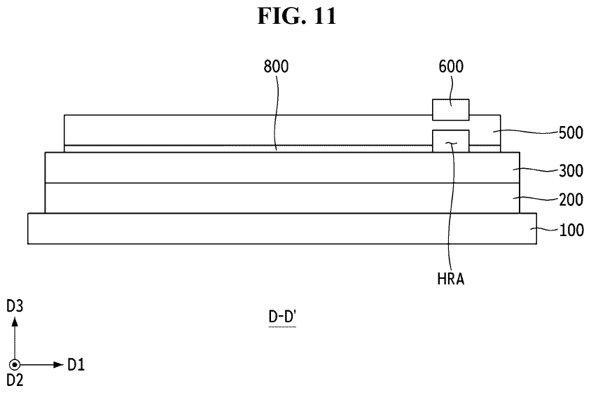

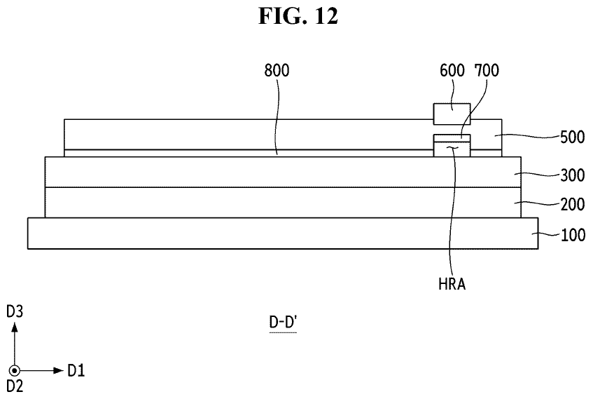

FIG. 8 is a plan view illustrating a display device according to a second embodiment of the present disclosure when a connecting member is unfolded. FIG. 9 is a view illustrating the display device illustrated in FIG. 8 when the connecting member is bent. FIG. 10 is an enlarged view of portion C of FIG. 9. FIG. 11 is a cross-sectional view taken along line D-D′ of FIG. 10. FIG. 12 is a view illustrating the heat dissipation member placed in the heat dissipation space in FIG. 11.

Referring to FIGS. 8 to 12, a display device 10 according to the second embodiment of the present disclosure may include a cover window 100, a display panel 200, a panel support member 300, a connecting member 400, a circuit board 500, a touch integrated circuit 600, a heat dissipation member 700, and an adhesive sheet 800.

The cover window 100, the display panel 200, the panel support member 300, the connecting member 400 and the touch integrated circuit 600 are identical to those of the first embodiment; and, therefore, the redundant descriptions will be omitted.

The circuit board 500 may be electrically connected to the display panel 200 by the connecting member 400. The circuit board 500 may be a flexible printed circuit board (FPCB) that can be bent, a rigid printed circuit board (PCB) that is not easily bent, or a composite printed circuit board including both a rigid printed circuit board and a flexible printed circuit board. The circuit board 500 may overlap with the panel support member 300 when the connecting member 400 is bent.

The circuit board 500 may process the signal converted by a control circuit board (not illustrated) and transmit signal to the display panel 200.

A heat release area HRA may be formed at the circuit board 500. The heat release area HRA may be formed as a groove depressed into the circuit board 500 from a surface of the circuit board 500 (the lower surface in the third direction of FIG. 12). The shape of the heat release area HRA may conform to the shape of the touch integrated circuit 600 when viewed from the top. The heat release area HRA may be formed under the touch integrated circuit 600 in the third direction D3 of FIG. 12 such that the heat release area HRA is in line with the touch integrated circuit 600.

The heat dissipation member 700 may be located inside the heat release area HRA. The heat dissipation member 700 may be provided as a heat dissipation sheet having a thickness. The shape of the heat dissipation member 700 may conform to the shape of the touch integrated circuit 600 when viewed from the top. The heat dissipation member 700 may overlap with the touch integrated circuit 600 inside the heat release area HRA. The heat dissipation member 700 may be placed on the upper surface of the inner surfaces of the heat release area HRA in the third direction D3 of FIG. 12.

The adhesive sheet 800 may overlap the panel support member 300. The adhesive sheet 800 may be placed between the panel support member 300 and the circuit board 500 when the connecting member 400 is bent. For example, the upper surface of the panel support member 300 in the third direction D3 of FIG. 12 and the lower surface of the circuit board 500 in the third direction D3 of FIG. 12 may be in contact with the adhesive sheet 800. Accordingly, the panel support member 300 and the circuit board 500 can be coupled with each other.

A part of the adhesive sheet 800 may be removed, such that a removal area may be formed. The shape of the removed part of the adhesive sheet 800 may conform to the shape of the heat release area HRA when viewed from the top. The removed part of the adhesive sheet 800 may overlap with the heat release area HRA.

As described herein, the heat release area HRA and the heat dissipation member 700 overlap with the touch integrated circuit 600, and the heat release area HRA and the heat dissipation member 700 are arranged between the display panel 200 and the touch integrated circuit 600, such that the heat release area HRA and the heat dissipation member 700 may prevent heat generated in the touch integrated circuit 600 from being directly transferred to the display panel 200.

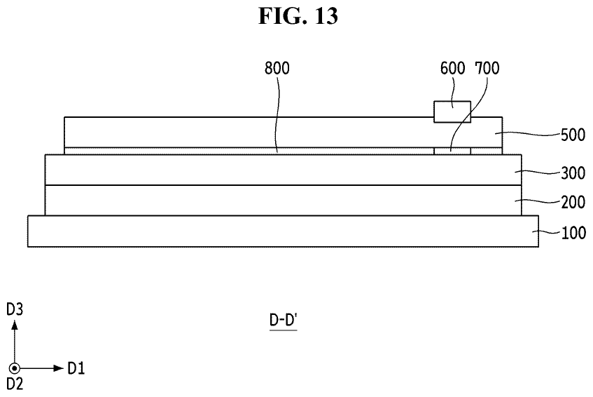

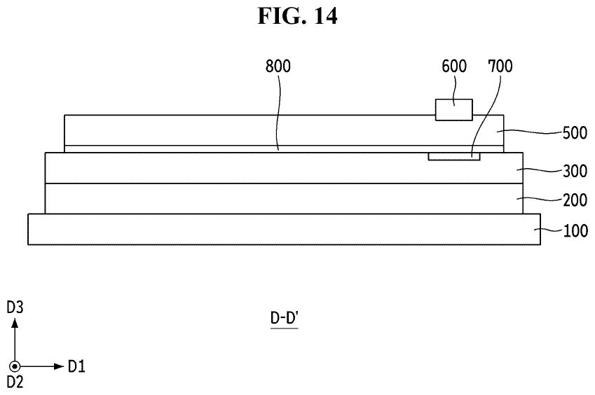

FIG. 13 is a view illustrating a heat dissipation member placed inside an adhesive sheet. FIG. 14 is a view illustrating a heat dissipation member placed inside a panel support member.

Referring to FIGS. 13 and 14, a display device 10 according to a third embodiment of the present disclosure may include a cover window 100, a display panel 200, a panel support member 300, a connecting member 400, a circuit board 500, a touch integrated circuit 600, a heat dissipation member 700, and an adhesive sheet 800.

The cover window 100, the display panel 200, the panel support member 300, the connecting member 400, the circuit board 500, the touch integrated circuit 600 and the adhesive sheet 800 are identical to those of the second embodiment; and, therefore, the redundant descriptions will be omitted. It should be noted, however, that no heat release area HRA is formed in the circuit board 500 according to the third embodiment.

The heat dissipation member 700 may be placed inside the adhesive sheet 800. For example, a part of the adhesive sheet 800 is removed, and the heat dissipation member 700 may be placed in that part. The thickness of the heat dissipation member 700 may equal to the thickness of the adhesive sheet 800.

The shape of the heat dissipation member 700 may conform to the shape of the touch integrated circuit 600 when viewed from the top. The heat dissipation member 700 may be located under the touch integrated circuit 600 in the third direction D3 as illustrated in FIG. 13 such that the heat dissipation member 700 is in line with the touch integrated circuit 600. The heat dissipation member 700 may be in contact with the panel support member 300 and the circuit board 500.

Alternatively, the heat dissipation member 700 may be placed inside the panel support member 300. The heat dissipation member 700 may be provided as a heat dissipation sheet having a thickness. The shape of the heat dissipation member 700 may conform to the shape of the touch integrated circuit 600 when viewed from the top, and the area of the heat dissipation member 700 may be larger than the area of the touch integrated circuit 600 when viewed from the top.

The heat dissipation member 700 may be embedded into the panel support member 300 from the upper surface in the third direction D3 as illustrated in FIG. 14. Accordingly, the heat dissipation member 700 may be in contact with the adhesive sheet 800.

The heat dissipation member 700 may overlap with the touch integrated circuit 600. For example, the heat dissipation member 700 may be located under the touch integrated circuit 600 in the third direction D3 of FIG. 14 such that the heat dissipation member 700 is in line with the touch integrated circuit 600.

As described herein, the heat dissipation member 700 overlaps with the touch integrated circuit 600, and the heat dissipation member 700 is placed between the display panel 200 and the touch integrated circuit 600, such that the heat dissipation member 700 may prevent heat generated in the touch integrated circuit 600 from being directly transferred to the display panel 200.

The display device according to the embodiment of the present disclosure may be applied to a variety of electronic devices. An electronic device according to an embodiment includes the display device described herein, and may further include a module or device having additional features in addition to the display device.

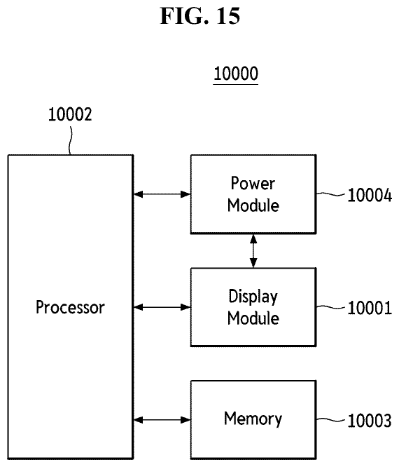

FIG. 15 is a block diagram of an electronic device according to an embodiment of the present disclosure.

Referring to FIG. 15, an electronic device 10000 according to an embodiment of the present disclosure may include a display module 10001, a processor 10002, a memory 10003, and a power module 10004.

The processor 10002 may include at least one of: a central processing unit (CPU), an application processor (AP), a graphic processing unit (GPU), a communication processor (CP), an image signal processor (ISP), and a controller.

The memory 10003 may store data information supportive of the operation of the processor 10002 or the display module 10001. In an example in which the processor 10002 executes an application stored in the memory 10003, an image data signal and/or an input control signal may be transmitted to the display module 10001. The display module 10001 may process the received signal and output image information through a display screen.

The power module 10004 may include a power supply module such as a power adapter and a battery device, and a power conversion module that converts the power supplied by the power supply module to generate power for the operation of the electronic device 10000.

At least one of the elements of the electronic device 10000 described herein may be included in the display devices according to the embodiments described herein. In some aspects, some of the individual modules functioning as a single module may be included in the display device while some others may be provided separately from the display device. For example, the display device may include the display module 10001, and the processor 10002, the memory 10003 and the power module 10004 may be implemented as other devices inside the electronic device 10000 instead of the display device.

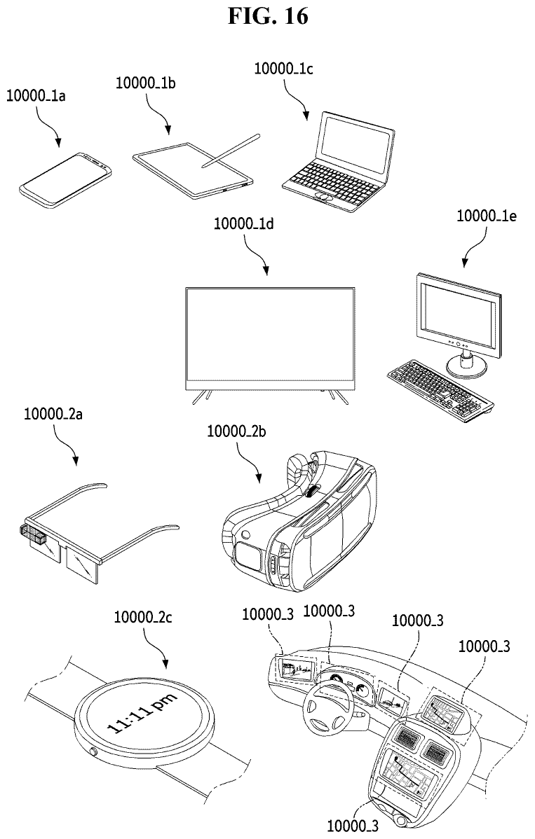

FIG. 16 is a view illustrating electronic devices according to a variety of embodiments of the present disclosure.

Referring to FIG. 16, a variety of electronic devices employing display devices according to embodiments may include not only image display electronic devices such as a smart phone 10000_1a, a tablet PC 10000_1b, a laptop computer 10000_1c, a TV 10000_1d and a desktop monitor 10000_1e, but also wearable electronic devices including display modules such as smart glasses 10000_2a, a head-mounted display 10000_2b and a smart watch 10000_2c, and electronic devices for vehicles 10000_3 including display modules such as a center information display (CID) placed on the dashboard, the center fascia and the dashboard of a vehicle, and a room mirror display.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a display panel;
a panel support member overlapping with the display panel;
a connecting member connected to the display panel;
a circuit board connected to the connecting member and comprising a touch integrated circuit; and
a heat dissipation member which dissipates heat generated in the touch integrated circuit.

2. The display device of claim 1, wherein:
the touch integrated circuit protrudes from the circuit board, and
the heat dissipation member covers at least a part of the touch integrated circuit.

3. The display device of claim 2, wherein the heat dissipation member entirely covers a protruding surface and side surfaces of the touch integrated circuit.

4. The display device of claim 3, wherein the heat dissipation member comprises:
a first heat dissipation member covering the protruding surface of the touch integrated circuit; and
a second heat dissipation member covering the side surfaces of the touch integrated circuit and side surfaces of the first heat dissipation member.

5. The display device of claim 4, wherein the side surfaces of the touch integrated circuit covered by the second heat dissipation member protrude from the circuit board.

6. The display device of claim 1, wherein:
the circuit board overlaps with the panel support member when the connecting member is bent, and
the heat dissipation member is placed inside the panel support member.

7. The display device of claim 6, wherein the heat dissipation member overlaps with the touch integrated circuit.

8. The display device of claim 6, further comprising:
an adhesive sheet arranged between the panel support member and the circuit board,
wherein the heat dissipation member is in contact with the adhesive sheet.

9. The display device of claim 1, further comprising:
an adhesive sheet overlapping with the panel support member,
wherein:
the circuit board comes into contact with the adhesive sheet when the connecting member is bent, and
the heat dissipation member is placed inside the adhesive sheet.

10. The display device of claim 9, wherein the heat dissipation member overlaps with the touch integrated circuit.

11. The display device of claim 9, wherein the heat dissipation member is in contact with the panel support member and the circuit board.

12. A display device comprising:
a display panel;
a panel support member overlapping with the display panel;
a connecting member connected to the display panel; and
a circuit board connected to the connecting member and comprising a touch integrated circuit,
wherein a heat release area formed in the circuit board is overlapping with the touch integrated circuit.

13. The display device of claim 12, further comprising:
an adhesive sheet overlapping with the panel support member,
wherein the circuit board comes into contact with the adhesive sheet when the connecting member is bent.

14. The display device of claim 13, wherein:
the heat release area is depressed into the circuit board from a surface of the circuit board, and
the surface of the circuit board comes in contact with the adhesive sheet when the connecting member is bent.

15. The display device of claim 14, wherein:
a part of the adhesive sheet is removed such that a removal area is formed, and
the removal area overlaps with the heat release area.

16. The display device of claim 12, further comprising:
a heat dissipation member placed inside the heat release area.

17. The display device of claim 16, wherein the heat dissipation member overlaps with the touch integrated circuit.

18. An electronic device comprising:
a display panel;
a panel support member overlapping with the display panel;
a connecting member connected to the display panel;
a circuit board connected to the connecting member and comprising a touch integrated circuit; and
a heat dissipation member which dissipates heat generated in the touch integrated circuit.

19. The electronic device of claim 18, wherein:
the touch integrated circuit protrudes from the circuit board, and
the heat dissipation member covers at least a part of the touch integrated circuit.

20. The electronic device of claim 18, further comprising: at least one of a processor;
a memory in which data on one or more of the display panel and the processor is stored; and
a power module which supplies power to the display panel, the processor and the memory.
